(19) United States
(12) Patent Application Publication
(10) Pub. No.: US 2003/0183943 A1
(43) Pub. Date: Oct. 2, 2003

(54) Integrated circuit die and an electronic assembly having a three-dimensional interconnection scheme

(76) Inventors: Johanna M. Swan, Scottsdale, AZ (US); Bala Natarajan, Phoenix, AZ (US); Chien Chiang, Fremont, CA (US); Greg Atwood, San Jose, CA (US); Valluri R. Rao, Saratoga, CA (US)

Correspondence Address: Stephen M. De Klerk, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/113,016

(22) Filed: Mar. 28, 2002

(51) Int. Cl. H01L 21/44; H01L 21/48; H01L 21/50; H01L 23/02; H01L 29/40

(52) U.S. Cl. 257/777; 438/106; 438/107; 438/108; 438/598; 257/678

(57) ABSTRACT

An electronic assembly is assembling by stacking two or more integrated circuit dies on top of one another. An opening is formed into a lower portion of an upper die, and subsequently filled with a conductive member. The conductive member is located on a lower die, and the conductive member interconnects integrated circuits of the upper and lower dies. The opening is formed through a lower portion only of the upper die so that it does not take up “real estate” over reserved for metal layers of the integrated circuit. By making the opening after the integrated circuit is manufactured, the location of the conductive member can be customized after the integrated circuit is formed, and so provides more flexibility when interconnecting with dies from different manufacturers.

### BACKGROUND OF THE INVENTION

1). Field of the Invention

This invention relates to an electronic assembly of the kind having a plurality of integrated circuit dies stacked onto one another, and its manufacture.

2). Discussion of Related Art

In conventional computer assemblies, integrated circuits are “two-dimensionally” connected to one another. Two dies may, for example, be mounted to a common substrate having metal lines that interconnect the integrated circuits of the dies with one another. A “three-dimensional” interconnection scheme may in certain instances be more desirable. Handheld devices may, for example, require a more compact packaging arrangement. In other applications, the metal lines in substrates may inhibit performance. Other applications may also require a three-dimensional interconnection scheme to allow for the design of more sophisticated, three-dimensional logic.

Some techniques for forming contacts on a substrate side of a die are disclosed in U.S. Pat. No. 6,184,060. These techniques are in some respects undesirable, because they require the formation of conductive members that take up metallization real estate. The conductive members are also formed prior to integrated circuit fabrication, which allows for less flexibility when interconnecting the integrated circuit dies from different manufacturers.

### BRIEF DESCRIPTION OF THE DRAWINGS

The invention is described by way of example with reference to the accompanying drawings, wherein:

FIG. 1 is a cross-sectional side view through a wafer, illustrating a portion of a die having an opening formed in a lower part;

FIG. 2 is a view similar to FIG. 1 after an oxide layer is formed on a lower surface of the die and within the opening;

FIG. 3 is a view similar to FIG. 2 after an opening is etched through an internal portion of the oxide layer and through a lower interlayer dielectric layer to a contact pad in the die;

FIG. 4 is a view similar to FIG. 3 after a tantalum nitride layer is blanket-sputtered over the oxide layer and onto the metal pad;

FIG. 5 is a view similar to FIG. 4, after the tantalum nitride layer is patterned and a copper conductive member is plated on the tantalum nitride layer;

FIG. 6 is a side view of a partially fabricated electronic assembly according to an embodiment of the invention, wherein the die of FIG. 5, another die, and a package substrate are stacked on one another;

FIG. 7 is a view similar to FIG. 6 after heating and cooling of the electronic assembly; and

FIG. 8 is a cross-sectional plan view on 8-8 in FIG. 7.

### DETAILED DESCRIPTION OF THE INVENTION

The following description relates to the construction of an electronic assembly by stacking two or more integrated circuit dies on top of one another. An opening is formed into a lower portion of an upper die, and subsequently filled with a conductive member. The conductive member is located on a lower die and interconnects integrated circuits of the upper and lower dies. The opening is formed through a lower portion only of the upper die so that it does not take up “real estate” reserved for metal layers of the integrated circuit. By making the opening after the integrated circuit is manufactured, the location of the conductive member can be customized after the integrated circuit is formed, and so provides more flexibility when interconnecting with dies from different manufacturers.

Referring now to FIG. 1, a portion of a fabricated wafer is shown, including a die 10 having a silicon substrate 12 and an integrated circuit 14 formed on the silicon substrate 12. The die 10 further includes a contact pad 16 and a passivation layer 18.

The silicon substrate 12 has a lower surface 20 and an upper surface 22. Individual transistors 24 and other electronic components are formed in and on the upper surface 22. The silicon substrate 12 is shown after having been thinned down in a grinding operation from between 425 and 750 microns to approximately 150 microns.

The integrated circuit 14 has a first interlayer dielectric layer 26 formed on the upper surface 22. A first metallization layer 28 is formed on the interlayer dielectric layer 26. The metallization layer 28 has disconnected portions. Some of the portions are connected to the transistors 24, and one of the portions forms a metal pad 30.

Alternating interlayer dielectric layers 32 and metallization layers 34 are subsequently formed on top of the first metallization layer 28. The contact pad 16 and the passivation layer 18 are formed on top of the final interlayer dielectric layer 32. The passivation layer 18 has a periphery that seals with the contact pad 16 and through which an upper surface of the contact pad 16 is exposed. The contact pad 16 is connected through portions of the metallization layers 28 and 34, plugs and vias (not shown), to the transistors 24. The metal pad 30 is also connected through portions of the metallization layers 28 and 34, plugs and vias (not shown) to the transistors 24. Signals can thus be transmitted to and from the transistors 24 through either the contact pad 16 or the metal pad 30.

A mask 40 is formed on the lower surface 20, and an opening 42 is formed in the mask 40 utilizing known photolithographic techniques. The opening 42 is aligned with the metal pad 30 and has a diameter of between 25 and 50 microns. A cavity is defined by the lower surface 20, and the opening 42 is exposed to an etchant that removes silicon but not the carbon material of the mask 40. An anisotropic etchant is used so that an opening 44 is formed in the silicon substrate 12 having a shape which substantially conforms to the shape of the opening 42. Etching is continued until the opening 44 reaches the interlayer dielectric layer 26. The etchant does not remove the oxide material of the interlayer dielectric layer 26, so that the interlayer dielectric layer 26 acts as an etch stop. The mask 40 is then removed so that the lower surface 20 is exposed.

As shown in FIG. 2, an oxide layer 48 is deposited on the silicon substrate 12, followed by a mask 50. The oxide layer 48 is blanket-deposited so that it covers the lower surface 20, side surfaces of the opening 44, and a lower surface of the interlayer dielectric layer 26. The mask 50 covers all surfaces of the oxide layer 48. The mask 50 is subsequently patterned to define an opening 52. The opening 52 is aligned with the metal pad 30, and exposes a lower surface of a portion 53 of the oxide layer 48 located on the interlayer dielectric layer 26.

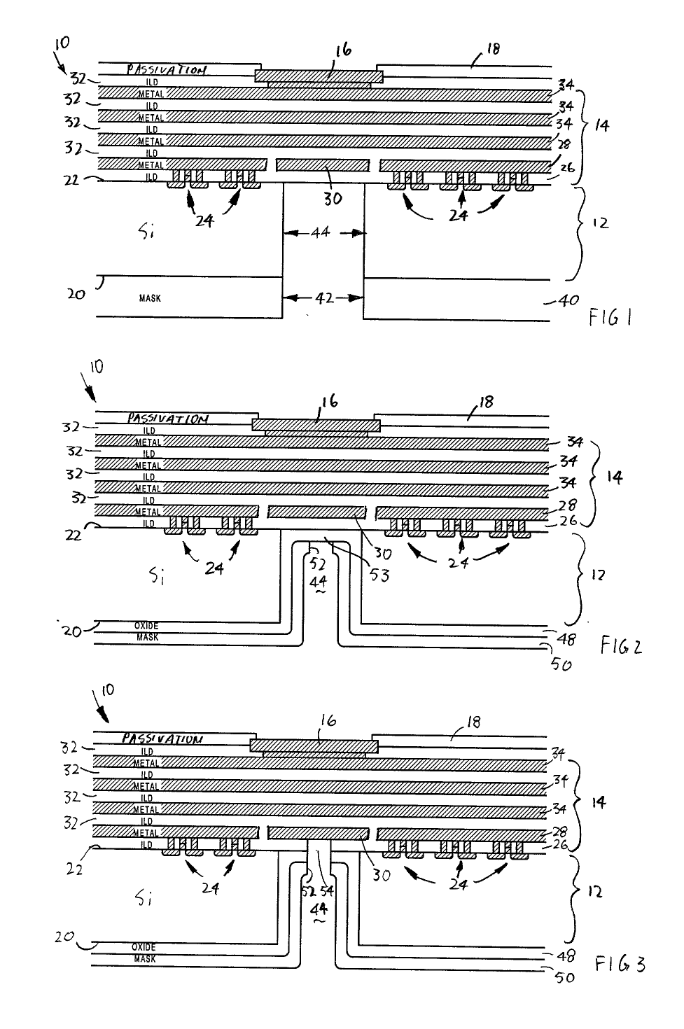

As illustrated in FIG. 3, an opening 54 is subsequently etched in the oxide layer 48 and the interlayer dielectric layer 26. An etchant is introduced into the openings 44 and 52, and a lower surface of the oxide layer 48 is exposed to the etchant. The etchant is thus different from the etchant used for forming the opening 44. An anisotropic etchant is used so that the opening 54 has a shape which substantially conforms to a shape of the opening 52. The etchant removes the material of the oxide layer 48 and the oxide material of the interlayer dielectric layer 26. The etchant does not remove the metal of the metal pad 30, so that the metal pad 30 acts as an etch stop. The lower surface of the metal pad 30 is exposed after the opening 54 is etched. The mask 50 is then removed.

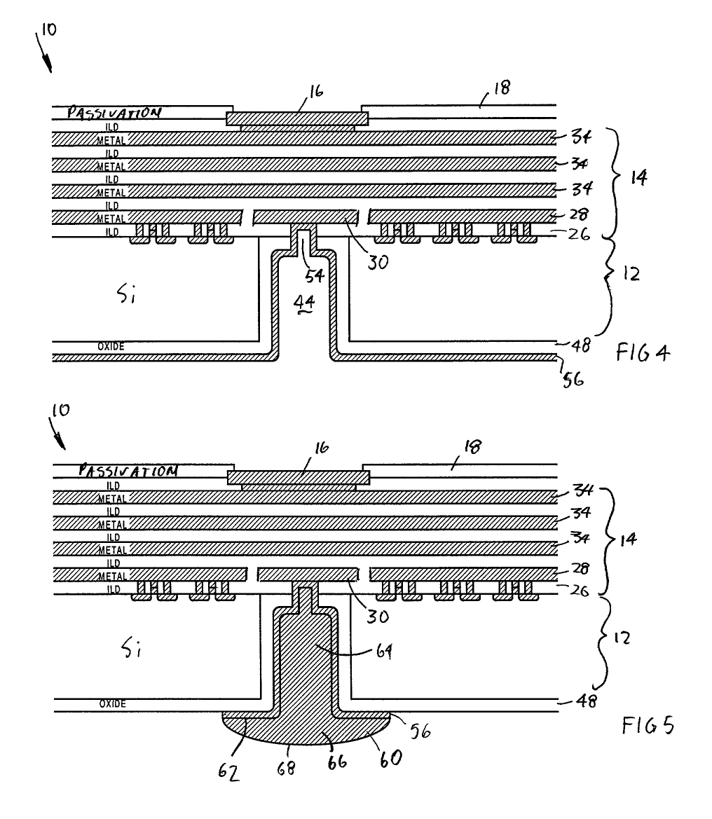

As illustrated in FIG. 4, a tantalum nitride layer 56 is subsequently blanket-sputtered on the oxide layer 48. The tantalum nitride layer 56 forms on the metal pad 30, side surfaces of the openings 54 and 44, and a lower surface of the oxide layer 48. The oxide layer 48 provides a surface onto which the tantalum nitride layer 56 can easily be sputtered, and also provides electrical insulation between the tantalum nitride layer 56 and the surrounding silicon. Techniques exist in the art for sputtering tantalum nitride on oxide within openings such as the opening 44.

FIG. 5 illustrates the structure of FIG. 4 after the tantalum nitride layer 56 is patterned and a copper conductive member 60 is formed. The tantalum nitride layer 56 is patterned by forming a mask over portions of the tantalum nitride layer 56 within the openings 44 and 54, and also over a circular portion thereof surrounding the opening 44 on a lower surface of the oxide layer 48. Other portions of the tantalum nitride layer 56 are removed. The tantalum nitride layer 56 forms a circular contact pad 62 on a lower surface of the oxide layer 48.

The copper conductive member 60 is plated on the remaining tantalum nitride layer 56. The tantalum nitride layer 56 acts as a seed layer for forming the conductive member 60. The tantalum nitride layer 56 also acts as a barrier layer, preventing migration of copper from the conductive member 60 into the silicon of the substrate 12. Plating is continued until the openings 54 and 44 (FIG. 4) are filled with a portion 64 of the conductive member 60 and until the conductive member 60 forms a bump 66 on the contact pad 62. The bump 66 is connected through the portion 64 to the metal pad 30. The bump 66 has a lower surface 68 standing proud of the lower surface of the oxide layer 48. Bumps may then be formed on every contact pad 16, and the wafer is then singulated into individual dies so that the die 10 is separated from other dies of the wafer.

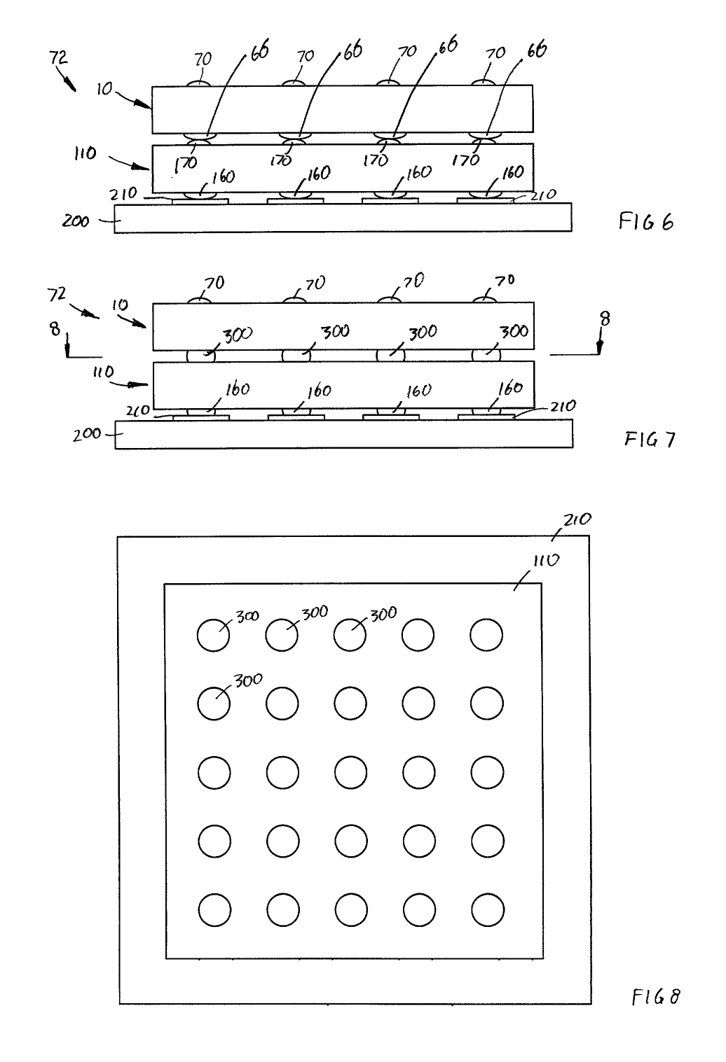

FIG. 6 illustrates a partially assembled electronic assembly 72, including the die 10. The die 10 includes a plurality of bumps 66 manufactured in a similar manner. The die 10 includes a plurality of the contact pads 16 of FIG. 5, and a respective bump 70 is plated on each one of the contact pads 16.

The electronic assembly 72 also includes another die 110 and a package substrate 200. The die 110 may be manufactured in exactly the same way as the die 10. It may also be possible that the dies 10 and 110 are exactly the same in all respects. The dies 10 and 110 may, for example, be identical memory dies. Alternatively, the dies 10 and 110 may differ from one another and may even be from different manufacturers. One die may, for example, be a processor, and the other die a memory die. What should be noted is that the die 110 also includes bumps 170 and 160 at the top and the bottom, respectively. The bumps at the top may not be necessary, and merely assist in alignment during subsequent reflow. The die 10 is stacked on the die 110, and a respective one of the bumps 66 is positioned on a respective one of the bumps 170. The package substrate 200 has a plurality of contact terminals 210 on an upper surface thereof. Each one of the bumps 160 is positioned on a respective one of the contact terminals 210.

FIG. 7 illustrates the electronic assembly 72 of FIG. 6 after being processed through a reflow furnace. The electronic assembly 72 is heated so that the bumps 66, 170, and 160 melt, and are subsequently cooled. The bumps 66 thereby attach to the bumps 170 to form interconnects 300. The interconnects 300 structurally attach the die 10 to the die 110. The interconnects 300 also electrically connect the integrated circuit of the die 10 with the integrated circuit of the die 110. Other bumps 160 attach the die 110 to the package substrate 200 and interconnect the integrated circuit of the die 110 with metallization layers in the package substrate 200.

As illustrated in FIG. 8, the interconnects 300 are in an array of rows and columns. A typical array may, for example, have ten rows and eight columns. Although only the interconnects 300 are shown in FIG. 8, it will be understood that an array of conductive members such as the conductive member 60 shown in FIG. 5 are formed in an array which corresponds to the array of the interconnects 300.

An electronic assembly 72 is thus provided, wherein two (or more) integrated circuit dies are stacked on top of one another. Because the opening 44 is formed through a lower portion only of the upper die 10, it does not take up “real estate” reserved for the metallization layers 28 and 34 of the integrated circuit 14. By making the opening 44 after the integrated circuit is manufactured, the location of the conductive member can be customized after the integrated circuit 14 is formed, and so provide more flexibility when interconnected with the die 110.

An additional benefit of the electronic assembly 72 is that the die 10 provides the structural interconnection benefits of a flip-chip die, while providing the thermal benefits of a wire-bonded die. Because the integrated circuit 14 is at the top, it can be more easily cooled with a heat sink closer to the active circuitry than in a conventional flip-chip application. However, because the die 10 is structurally and electrically connected through an array of bumps 66, the structural and electrical benefits of a flip-chip application are achieved. A further advantage of having conductive members on vias in the silicon below the integrated circuit is that they are more thermally conductive than the silicon and assist in dissipation of heat.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A method of constructing an electronic assembly, comprising:
forming an opening into one surface of a first substrate of a first die having a first integrated circuit formed on an opposing surface of the first substrate;
forming a conductive member in the opening, the conductive member being electrically connected to the first integrated circuit; and
stacking the first die on a second component having a circuit, the first integrated circuit being connected through the conductive member to the circuit of the second component.

2. The method of claim 1, wherein the first opening is formed through a portion only of the first die.

3. The method of claim 1, wherein the first opening is etched into the first substrate.

4. The method of claim 3, wherein a first etchant is used to etch through the first substrate and a second, different etchant is used to etch through a dielectric layer of the first integrated circuit to form the first opening.

5. The method of claim 4, wherein the dielectric layer acts as an etch stop for the first etchant.

6. The method of claim 1, further comprising:
forming an oxide layer on surfaces of the opening after forming at least a portion of the first opening.

7. The method of claim 6, wherein the portion of the opening is etched with a first etchant, whereafter the oxide layer is etched with a second, different etchant.

8. The method of claim 7, wherein the second etchant is used to etch through a dielectric layer to a contact of the first integrated circuit.

9. The method of claim 6, further comprising:
forming a metal layer on the oxide layer prior to forming the conductive member.

10. The method of claim 9, wherein the metal layer is sputtered and the conductive member is plated on the metal layer.

11. The method of claim 9, wherein the metal layer and the conductive member are of different materials.

12. The method of claim 11, wherein the materials include tantalum nitride and copper, respectively.

13. The method of claim 1, wherein the conductive member is located on a terminal of the second die.

14. The method of claim 1, wherein a plurality of said openings are formed, a respective conductive member is formed in each opening, and the circuits are connected through the conductive members.

15. The method of claim 1, wherein the second component has a second substrate and the circuit of the second component is a second integrated circuit formed on the second substrate.

16. The method of claim 15, further comprising:
forming an opening into one surface of the second substrate opposing the second integrated circuit; and
forming a conductive member in the opening in the second substrate.

17. A method of constructing an electronic assembly, comprising:
forming an opening into a first surface of a substrate of a first die having an integrated circuit formed on a second, opposing surface of the substrate; and
forming a conductive member in the opening, the conductive member being electrically connected to the integrated circuit and having a surface standing proud of the first surface.

18. The method of claim 17, wherein the first opening is formed through a portion only of the first die.

19. The method of claim 17, further comprising:
locating the surface of the conductive member on a terminal of a second die, the conductive member interconnecting the integrated circuit of the first die with an integrated circuit of the second die.

20. An electronic assembly comprising:
a first substrate having a lower surface and an upper surface;
a first integrated circuit formed on the upper surface of the first substrate to jointly form a first die;
a conductive member located in the substrate and extending through a portion only of the first die; and
a second component including a second circuit, the first die being stacked on the second component and the first and second circuits being connected through the conductive member.

21. The electronic assembly of claim 20, wherein the conductive member has a lower surface which is brought into contact with a terminal of the second component.

22. The electronic assembly of claim 20, further comprising:
an oxide layer between the conductive member and the first substrate.

23. The electronic assembly of claim 22, further comprising:
a metal barrier layer between the conductive member and the substrate, the metal barrier layer being of a different material than the conductive member.

24. The electronic assembly of claim 20, wherein the second component has a second substrate and the circuit of the second component is a second integrated circuit formed on the second substrate.
